(19) United States
(12) Patent Application Publication
(10) Pub. No.: US 2013/0250657 A1
(43) Pub. Date: Sep. 26, 2013

(54) System and Method for Writing Data to an RRAM Cell

(71) Applicant: Rambus Inc., Sunnyvale, CA (US)

(72) Inventors: Brent Steven Haukness, Monte Sereno, CA (US); Mark D. Kellam, Siler City, NC (US); Gary B. Bronner, Los Angeles, CA (US); Craig Hampel, Los Altos, CA (US)

(73) Assignee: Rambus Inc., Sunnyvale, CA (US)

(21) Appl. No.: 13/789,543

(22) Filed: Mar. 7, 2013

Related U.S. Application Data
(60) Provisional application No. 61/608,061, filed on Mar. 7, 2012.

(51) Int. Cl. G11C 13/00

(52) U.S. Cl. CPC G11C 13/0069
USPC 365/148

(57) ABSTRACT

A resistive RAM device includes a bit line, a word line, an RRAM cell coupled to the word line and to the bit line, a write driver and a disable circuit. The write driver is coupled to the bit line. The disable circuit stops a write operation performed by the write driver on a respective RRAM cell when a predefined condition on the bit line is achieved. The predefined condition depends on a mode of operation of the RRAM cell.

### RELATED APPLICATIONS

This application claims priority to U.S. Provisional Application No. 61/608,061, filed Mar. 7, 2012, which is hereby incorporated by reference in its entirety.

### BACKGROUND

Resistive RAM (RRAM) cells are memory devices that store data based on the resistance of the RRAM cell (i.e., the resistance between the electrodes of the RRAM cell). In an example, an RRAM cell in a low resistance state (referred to as a “SET” state) represents a logic 1 and an RRAM cell in a high resistance state (referred to as a “RESET” state) represents a logic 0. An RRAM cell includes a resistive element composed of a layer of solid electrolyte (e.g., GeSe) located between a first electrode (an “ion source electrode”) that acts as a source of mobile metal ions and a second inert electrode.

In a set operation, a “set” voltage is applied between the electrodes of the RRAM cell to set the RRAM cell to its low resistance SET state. The set voltage causes metal ions to migrate from the ion source electrode through the electrolyte from the ion source electrode to the inert electrode. The ions deposit as metal on the inert electrode and form conductive filaments that extend towards the ion source electrode. Ion migration and metal deposition continue until at least one of the conductive filaments establishes a conductive path between the electrodes of the RRAM cell, which substantially reduces the resistance of the RRAM cell.

In a reset operation, a “reset” voltage, opposite in polarity to the set voltage, is applied between the electrodes of the RRAM cell to reset the RRAM cell to its high resistance RESET state. The reset voltage removes metal from the conductive filaments and drives the resulting the metal ions back toward the ion source electrode. The metal removal process breaks the conductive path between the electrodes, which increases the resistance of the RRAM cell.

During a set operation, once a conductive filament establishes a conductive path between the electrodes of the RRAM cell, continued application of the set voltage causes more metal ions to migrate and to (1) deposit metal on the conductive filament increasing the thickness (e.g., diameter, girth, etc.) of the conductive filament and/or (2) establish other conductive filaments that may establish additional conductive paths between the electrodes of the RRAM cell. Increasing the thickness of the conductive filament and/or forming additional conductive filaments reduces the likelihood that subsequent spontaneous diffusion of metal ions from the conductive filament, i.e., diffusion of metal ions not caused by the application of a reset voltage, will break all of the conductive path(s) between the electrodes and cause the RRAM cell to revert to the RESET state. Thus, continuing to apply the set voltage after the RRAM cell has been set to the SET state results in a better data retention time for the RRAM cell. However, continuing to apply the set voltage after the RRAM cell has been set to the SET state typically makes the RRAM cell more difficult to reset to the RESET state. For example, one or both of a greater current and a longer reset time may be needed to reset the RRAM cell to the RESET state. This impairs the write performance of the RRAM cell. To date, the “tension” between data retention time and write performance has been seen primarily as an engineering challenge to be overcome, rather than as opportunity to make new types of RRAM devices.

### BRIEF DESCRIPTION OF THE DRAWINGS

FIG. 1 is a block diagram showing an example of a resistive RAM device.

FIG. 2 is a block diagram showing an example of the resistive RAM device in which the disable circuit monitors bit line voltage.

FIGS. 3A and 3B are respectively a resistance versus time graph and a current and voltage versus time graph showing an example of a set operation.

FIG. 4 is a graph showing an example of the resistance ranges and exemplary target resistances associated with the set and reset states of an exemplary RRAM cell.

FIG. 5 is a block diagram showing an example of a resistive RAM device in which the disable circuit monitors bit line current.

FIG. 6 is a block diagram showing an example of a resistive RAM device in which the disable circuit additionally operates during reset operations.

FIG. 7A is a block diagram showing an example of an RRAM device having an array of RRAM cells.

FIG. 7B is a block diagram showing an example of a host device that includes the RRAM device shown in FIG. 7A.

FIG. 8A is a block diagram showing an example of RRAM device in which subsets of the RRAM cells in the RRAM device are operated in different modes of operation.

FIG. 8B is a block diagram showing an example the RRAM device shown in FIG. 8A in which a separate and distinct voltage/current generator is used for each subset of RRAM cells in the RRAM device.

FIG. 9 is a flowchart showing an example of a method for operating an RRAM device.

FIG. 10 is a flowchart showing an example of another method for operating an RRAM device.

Like reference numerals refer to corresponding parts throughout the drawings.

### DESCRIPTION OF EMBODIMENTS

In the descriptions provided below, is should be understood that, although the terms first, second, etc. may be used herein to describe various elements, these elements should not be limited by these terms. These terms are only used to distinguish one element from another. For example, a first node could be termed a second node, and, similarly, a second node could be termed a first node. The first node and the second node are both nodes, but they are not the same node.

The terminology used in this specification is for the purpose of describing particular embodiments only and is not intended to be limiting. As used in the detailed description of the embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Note that although the following discussion refers to RRAM cells (and/or devices) using conductive filaments of a type also known as conductive bridging RAM (CBRAM), the embodiments described herein may be applied to other types of memory cells (and/or devices) including, but not limited to other filament-based RRAM cells (and/or devices), non-filament-based RRAM cells (and/or devices), or phase change memory cells (and/or devices).

Some embodiments described below provide a write driver in an RRAM device having two or more modes of operation, each with a different combination of data retention time and write performance. The term “write performance” is used herein to represent the time required to perform a current write operation and a subsequent write operation (e.g., a reset operation following a set operation). In these embodiments, by controlling the write driver during a set operation, the characteristics of one or more RRAM cells can be controlled. For example, application of a set voltage to the RRAM cells during the set operation may be controlled to trade off between (1) data retention time and (2) the write time of a subsequently-performed reset operation.

The terms “resistive RAM device” and “RRAM device” are used in this disclosure to refer a device having one or more RRAM cells. For example, the terms may refer to device having a single RRAM cell, or to refer to a device having more than one RRAM cell (e.g., RRAM cells in an array of RRAM cells).

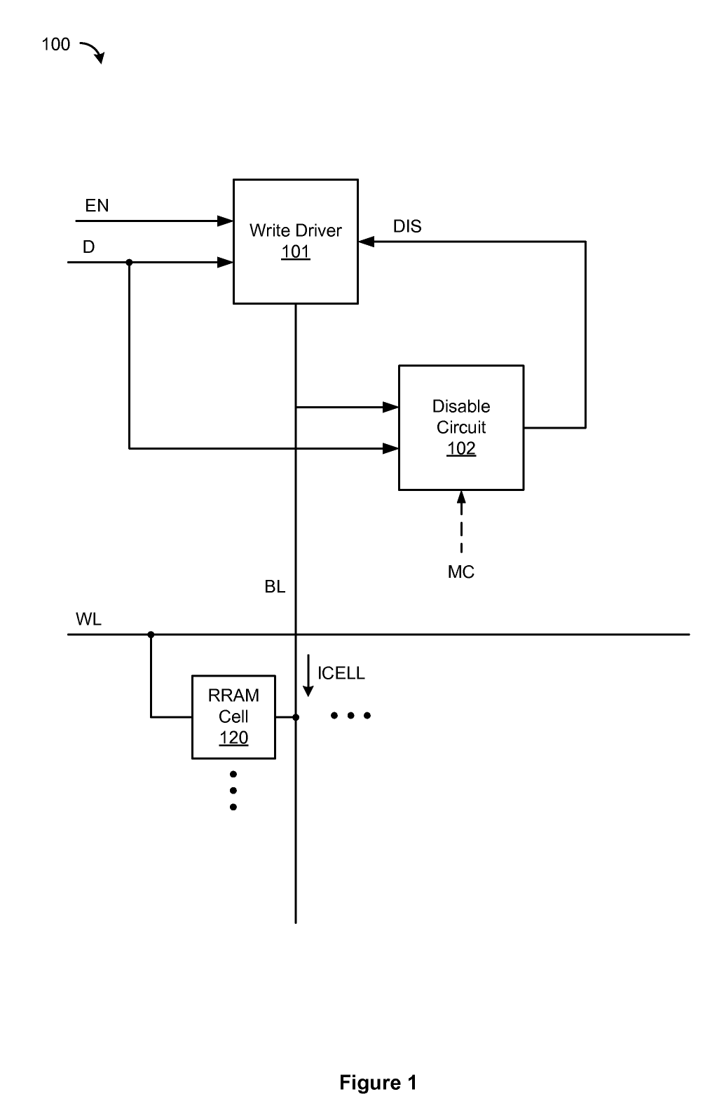

FIG. 1 is a block diagram showing an example of an RRAM device 100 in accordance with an embodiment. RRAM device 100 has a bit line BL, a word line WL, an RRAM cell 120 coupled between word line WL and bit line BL, a write driver 101 coupled to bit line BL and a disable circuit 102. Disable circuit 102 has an input connected to bit line BL, and an output connected to write driver 101. The disable circuit monitors the bit line, and stops write driver 101 from continuing to perform a write operation (a set operation or a reset operation) on RRAM cell 120 (or any other RRAM cell (not shown) coupled to bit line BL) when a predefined condition on bit line BL is achieved. The predefined condition depends on the mode of operation of the RRAM cell. For example, the predefined condition on the bit line corresponds to a specific trade-off between write performance and data retention. The write operation is typically a SET operation but may alternatively be a RESET operation.

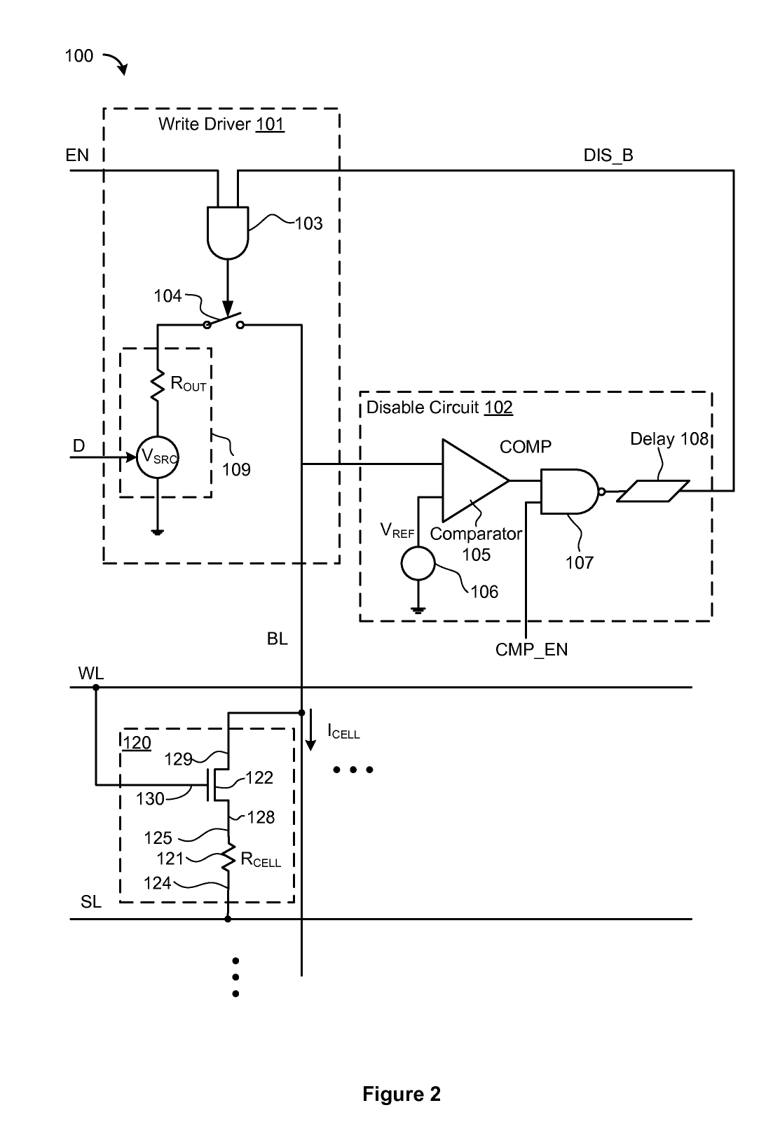

At the start of a write operation, word line WL is activated to select the row of RRAM cells of which RRAM cell 120 is part and a data signal D is supplied to write driver 101. Enable signal EN is then asserted to activate write driver 101. In response to the enable signal, write driver 101 supplies to bit line BL a voltage or current suitable to perform the write operation specified by data signal D. During the write operation, the voltage on the bit line provides a measure of the condition of RRAM cell 120. Alternatively, current in the bit line provides a measure of the condition of the RRAM cell. In an example, the voltage on or the current in the bit line provides a measure of the resistance of the resistive element (described below with reference to FIG. 2) of the RRAM cell. Once the condition of RRAM cell 120 is consistent with the mode of operation of the RRAM cell, there is no need to continue the write operation. Indeed, continuing the write operation would degrade a subsequent write operation of the opposite type (a RESET operation following a SET operation, or a SET operation following a RESET operation). Disable circuit 102 monitors bit line BL during the write operation. When it detects that the defined condition exists on the bit line, disable circuit 102 outputs a disable signal DIS to write driver 101. Disable signal DIS stops write driver 101 from continuing to perform the write operation with RRAM cell 120 in its defined condition and no more.

Performing a write operation only until a defined condition is detected on bit line BL and then stopping the write operation enables the RRAM cell to be written with a defined trade-off between write performance and data retention, and additionally allows the time allocated to perform a subsequent write operation of the opposite type to be reduced since the write time of the subsequent opposite-type write operation is shorter and more consistent.

In an example, write driver 101 has a non-zero output resistance and disable circuit 102 monitors voltage on bit line BL. At the start of a set operation, RRAM cell 120 is in its high-resistance RESET state so that, when write driver 101 applies the set voltage to the bit line, current in the bit line is insignificant and the voltage on the bit line is close to the nominal set voltage output by write driver 101. Once a conductive filament forms to establish a first conductive path between the electrodes of the resistive element of the RRAM cell in response to application of the set voltage, the resistance of the RRAM cell decreases significantly and the resulting significant current in the bit line changes the voltage on the bit line. Disable circuit 102 detects the voltage change on the bit line and, in response, changes the state of the disable signal DIS. The change in state of the disable signal output by the disable circuit stops write driver 101 from continuing to apply the set voltage to the bit line. Discontinuing application of the set voltage prevents the set voltage from causing additional material to be deposited. Such additional material would be deposited on the conductive filament that extends between the electrodes of the resistive element and/or would form additional conductive filaments that could establish additional conductive paths between the electrodes of the resistive element. The disable circuit stops the write driver from continuing to apply the set voltage when one or more conductive filaments have formed that collectively change the resistance of the RRAM cell to a defined resistance. The resistance of the RRAM cell resulting from formation of the conductive filament(s) depends on the voltage on bit line BL that causes the disable signal DIS output by disable circuit 102 to change state. The bit line voltage that causes disable signal DIS to change state can range from a voltage corresponding to the formation of a single conductive filament that just establishes a conductive path between the electrodes (corresponding to an operational mode in which the RRAM device has faster set and reset times and a shorter data retention time) to a voltage corresponding to formation of one or more well-formed conductive filaments that establish robust conductive paths between the electrodes (corresponding to an operational mode in which the RRAM device has slower set and reset times and a longer data retention time).

The just-described example of disable circuit 102 may additionally or alternatively control write driver 101 during a reset operation. At the start of a reset operation, RRAM cell 120 is in its low-resistance SET state so that, when write driver 101 applies the reset voltage to bit line BL, current in the bit line is significant and the voltage on the bit line differs from the nominal reset voltage output by write driver 101. Once all conductive paths between the electrodes in the resistive element of the RRAM cell have broken in response to application of the reset voltage, the resistance of the RRAM cell increases significantly, and the resulting decrease in the current in the bit line causes the voltage on the bit line to change. In response to disable circuit 102 detecting the voltage change on the bit line, the disable signal output by the disable circuit changes state to stop write driver 101 from continuing to apply the reset voltage to the bit line. Discontinuing application of the reset voltage to the bit line prevents the reset voltage from causing additional deposited material to be removed from the inert electrode of the resistive element. The disable circuit stops the write driver from continuing to apply the reset voltage when the resistance of RRAM cell 120 has increased to a defined resistance that depends on the bit line voltage at which the disable circuit operates. This bit line voltage can range from a voltage at which the last of the conductive paths between the electrodes has just been broken (corresponding to an operational mode in which RRAM cell 120 has faster set and reset times and a shorter data retention time) to a voltage at which of most of the conductive filaments have been removed from the inert electrode (corresponding to an operational mode in which RRAM cell 120 has slower set and reset times and a longer data retention time). The bit line voltage at which the last of the conductive paths between the electrodes has just been broken corresponds to faster set and reset times because the amount of material removed from the conductive filament(s) is only that needed to break all of the conductive paths between the electrodes (fast reset time) and relatively little material has to be deposited in the next set operation to re-form the broken conductive path (fast set time). In this case, at least one conductive filament extends from the inert electrode toward the ion source electrode, but does not form a conductive path between the electrodes. The bit line voltage at which most of the conductive filaments have been removed corresponds to slower set and reset times because most of the material of the conductive filament(s) has migrated back to the ion source electrode. Thus, in this operational mode, a large amount of material is removed from the conductive filament(s) in the reset operation (slow reset time) and a large amount of material has to be deposited in the next set operation to re-form the conductive filament(s) (slow set time).

In some embodiments having slower write performance and a longer data retention time, disable circuit 102 operates in response to the change in bit line voltage that occurs when the first conductive path has just been established or when the last conductive path has just been broken, but a delay circuit in the disable circuit delays the disable signal applied to write driver 101 by a suitable delay time. During a set operation, the delay time is a time sufficient for one or more robust conductive filaments to form in the resistive element. In the reset mode, the delay time is a time sufficient for the reset voltage to fully or partially remove the remains of the conductive filaments from the inert electrode.

In some embodiments, disable circuit 102 operates only during a set operation, and operation of the disable circuit 102 is inhibited when the state of data signal D corresponds to a reset operation. In other embodiments, disable circuit 102 operates during both set operations and reset operations, and the state of data signal D controls the operation of the disable circuit (e.g., the bit line voltage at which disable signal DIS changes state).

Some embodiments of RRAM device 100 operate in a single operational mode that provides a single combination of write performance and data retention time. Other embodiments operate in two or more operational modes, with each operational mode having a respective combination of write performance and data retention time. In some embodiments having two or more operational modes, disable circuit 102 changes the operational mode of RRAM device 100 automatically, e.g., in response to an external stimulus, or in response to a user command. In other embodiments having two or more operational modes, disable circuit 102 receives a mode control signal MC that defines the operational mode of the RRAM device. In an example, disable circuit 102 receives the mode control signal from a memory controller external to the RRAM device.

FIG. 2 is a block diagram 100 illustrating an example of write driver 101 and disable circuit 102 in which disable circuit 102 controls only set operations performed by write driver 101. Write driver 101 is connected by bit line BL to exemplary RRAM cell 120. Write driver 101 includes a controlled voltage source 109 that has an output resistance R_{OUT} and a nominal output voltage V_{SRC}. The nominal output voltage V_{SRC} generated by controlled voltage source 109 depends on the state of data signal D input to the controlled voltage source. In the example shown, controlled voltage source 109 generates a nominal output voltage corresponding to the set voltage of RRAM cell 120 when data signal D is in a 1 state, and generates a nominal output voltage corresponding to the reset voltage of the RRAM cell when the data signal is in a 0 state. An opposite relationship between nominal output voltage and data signal state can alternatively be used.

The output of controlled voltage source 109 is connected to bit line BL through an analog switch 104. Analog switch 104 can be embodied as, for example, a tri-state buffer, a transmission gate, a series FET, or another suitable analog switch. When analog switch 104 is closed, controlled voltage 109 drives a bit line BL to a predetermined voltage that depends on the output voltage V_{SRC} of the controlled voltage source. During a set operation, the voltage to which controlled voltage source 109 drives the bit line is initially close to the nominal set output voltage of the controlled voltage source so that the bit line voltage V_{BL} on the bit line is sufficient to set RRAM cell 120 to its SET state. During a RESET operation, the voltage to which controlled voltage source 109 drives the bit line is initially less than nominal reset output voltage of the controlled voltage source but is sufficient to reset the RRAM cell 120 to its RESET state.

Analog switch 104 is controlled by a gate 103. Gate 103 has a first input connected to receive enable signal EN and a second input connected to receive a disable signal DIS_B (sometimes herein called an inverse disable signal) from disable circuit 102, which will be described in more detail below. In the example shown, gate 103 is an AND gate. However, other logic gates may be used with an appropriate modification of the input signals EN and DIS. The output of gate 103 is connected to the control input of gate 103.

In the example shown, RRAM cell 120 is a three-terminal RRAM cell. Three-terminal RRAM cell 120 includes a resistive element 121 and a gate device 122 connected in series between bit line BL and a source line SL. The resistance of the resistive element 121 is R_{CELL}, the value of which depends on the resistance state of the resistive element. A first terminal 129 of gate device 122 is coupled to bit line BL, a second terminal 130 of gate device 122 is coupled to a word line WL, which typically runs orthogonal to bit line BL, a third terminal 128 of gate device 122 is coupled to a first terminal 125 of resistive element 121, and a second terminal 124 of the resistive element 121 is coupled to source line SL. In the example shown, an FET is used as gate device 122, and terminals 128, 129 and 130 are the source, drain and gate, respectively, of the FET. In another example (not shown), the order in which gate device 122 and resistive element 121 are connected in series between bit line BL and source line SL is reversed.

Three-terminal RRAM cell 120 is subject to memory operations by applying appropriate voltages to word line WL, bit line BL, and source line SL. In an example of a set operation, word line WL is set to a high voltage (e.g., V_{DD}) to cause gate device 122 to couple the second terminal 125 of resistive element 121 to bit line BL, bit line BL is set to a voltage V₁ and source line SL is set to a source line voltage V₂, where V₁>V₂, to apply across RRAM cell 120 a voltage of V₁-V₂, substantially equal to the set voltage V_{SET} of the RRAM cell. Set voltage V_{SET} is a voltage sufficient to set the RRAM cell 120 to its SET state. In an example of a reset operation, bit line BL is set to a voltage V₃ and source line SL is set to source line voltage V₂, where V₃<V₂, to apply across RRAM cell 120 a voltage of V₃−V₂, substantially equal to the reset voltage V_{RESET} of the RRAM cell. Reset voltage V_{RESET} is a voltage sufficient to reset RRAM cell 120 to its RESET state. In some embodiments, a source line driver (not shown) applies to source line SL a static and non-negative voltage, which is a positive voltage substantially equal in magnitude to the reset voltage V_{RESET} of RRAM cell 120. In other embodiments, source line SL is connected to ground, sometimes called circuit ground of the resistive RAM device. For a bipolar-type, solid electrolyte-based RRAM cell, set voltage V_{SET} is a positive voltage and reset voltage V_{RESET} is typically a negative voltage, whereas, for a unipolar-type, solid electrolyte-based RRAM cell, set voltage V_{SET} and reset voltage V_{RESET} typically have the same polarity.

As noted above, a source line driver (not shown) is used to apply to source line SL a static and non-negative source line voltage, V_{SL}. In an example of a set operation performed on RRAM cell 120, bit line BL is set to a voltage V₁=V_{SL}+V_{SET} to perform the set operation. In an example of a reset operation, bit line BL is set to a voltage V₃=V_{SL}−|V_{RESET}| to perform the reset operation. Source line voltage V_{SL} is typically a positive voltage equal to the magnitude of the reset voltage (e.g., a positive voltage equal in magnitude to reset voltage V_{RESET}), and write driver 101 sets bit line BL to a voltage V_{SL}+V_{SET} to perform a set operation and to a voltage of zero volts (e.g., V_{SL}−|V_{RESET}|=0V) to perform a reset operation. When RRAM cell 120 is part of an array of RRAM cells, multiple types of memory operations (e.g., set operations, reset operations, and/or read operations) may be performed concurrently on the RRAM cells controlled by the active word line by respective bit line drivers (not shown) applying appropriate voltages to respective bit lines (not shown) similar to bit line BL. Unactivated word lines are typically set substantially to zero volts (i.e., circuit ground) to turn off the gate devices of the RRAM cells controlled by such unactivated word lines.

In the example shown, disable circuit 102 includes a voltage comparator 105, a reference voltage source 106, an enable gate 107 and an optional delay circuit 108. Voltage comparator 105 has a first input connected to bit line BL, a second input connected to reference voltage source 106. Reference voltage source 106 generates a reference voltage V_{REF}. In the example shown, reference voltage source 106 generates reference voltage V_{REF} at a level corresponding to the voltage V_{BL} on bit line BL when RRAM cell 120 achieves a defined condition during the set operation.

Voltage comparator 105 compares the voltage V_{BL} on bit line BL with reference voltage V_{REF} and outputs a comparison signal COMP in a state that depends on the result of the comparison. In an example, voltage comparator 105 outputs comparison signal COMP in a low state when bit line voltage V_{BL} is greater than or equal to reference voltage V_{REF}, and in a high state when bit line voltage V_{BL} is less than reference voltage V_{REF}.

The output of voltage comparator 105 is connected to one input of enable gate 107. The other input of enable gate 107 is connected to receive a compare enable signal CMP_EN. In the example shown in FIG. 2, enable gate 107 is a two-input NAND gate. In other examples, another type of gate, an R-S latch, or another type of latch is used instead of enable gate 107.

In embodiments in which disable circuit 102 includes optional delay circuit 108, the output of enable gate 107 is connected to the input of delay circuit 108, and the output of delay circuit 108 provides disable signal DIS_B to gate 103. The delay circuit 108 delays changes in the output of enable gate 107 by a time t_{DLY} to produce disable signal DIS_B. In an embodiment in which disable circuit 102 lacks optional delay circuit 108, the output of enable gate 107 provides disable signal DIS_B to gate 103.

Prior to a set operation, word line WL is driven to a high voltage and data signal D in its high state causes controlled voltage source 109 to generate a nominal output voltage equal to the voltage V₁ of RRAM cell 120, e.g., V_{SRC}=V₁ during the set operation. Additionally, reference voltage source 106 outputs reference voltage V_{REF} at a level appropriate for a set operation, e.g., a voltage close to, but greater than, source line voltage V_{SL}. Enable signal EN is in a low state that holds the output of gate 103 in a low state. The low output state of gate 103 holds analog switch 104 open. With the analog switch 104 open, the bit line voltage V_{BL} on bit line BL is nominally equal to source line voltage V_{SL}. Since bit line voltage V_{BL} is less than reference voltage V_{REF}, voltage comparator 105 outputs comparison signal COMP in a high state. However, since compare enable signal CMP_EN is in a low state, which holds the output of enable gate 107 in a high state, disable circuit 102 outputs inverse disable signal DIS_B in a high state.

At the start of the set operation, enable signal EN goes high, but compare enable signal CMP_EN remains low and inverse disable signal DIS_B remains high. The high state of enable signal EN causes the output of gate 103 to go high, since inverse disable signal DIS_B on the other input of the gate is also high. The high state of the output of gate 103 causes analog switch 104 to close. In its closed state, analog switch 104 applies the nominal output voltage V_{SRC} of controlled voltage source 109 to bit line BL and bit line voltage V_{BL} rises towards the voltage V₁ output by voltage source 109. When bit line voltage V_{BL} exceeds reference voltage V_{REF}, comparison signal COMP output by voltage comparator 105 goes low, but since compare enable signal CMP_EN is also low, the output of enable gate 107 and, hence, inverse disable signal DIS_B remain high, and analog switch 104 remains closed.

Compare enable signal CMP_EN is then asserted (goes high) at a time intermediate the time bit line voltage V_{BL} exceeds reference voltage V_{REF} and the earliest time RRAM cell 120 can change to its SET state in response to the set voltage. However, the low state of comparison signal COMP holds the output of enable gate 107, and, hence, inverse disable signal DIS_B, high, and analog switch 104 remains closed.

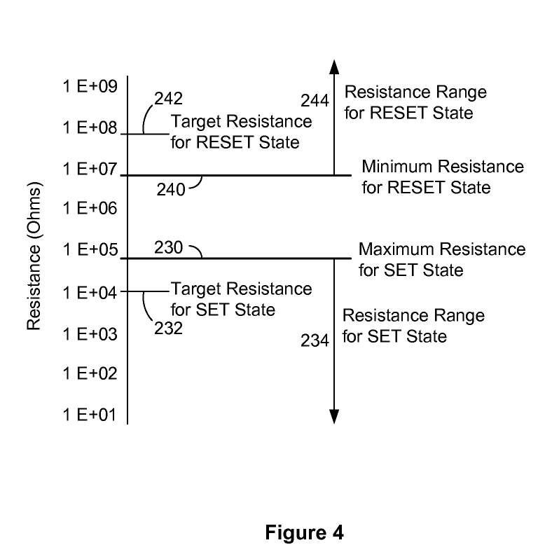

Application of the voltage V₁ to bit line BL causes RRAM cell 120 to undergo a set operation. When the set voltage has been applied for a time sufficient for a conductive filament to establish a conductive path in the resistive element 121 of the RRAM cell, the resistance of RRAM cell 120 decreases. As the resistance of the RRAM cell decreases, bit line voltage V_{BL} decreases due to the voltage divider formed by the output resistance R_{OUT} of controlled voltage source 109 and the resistance of RRAM cell 120. In another example, controlled voltage source 109 is a current-limited voltage source and the output voltage of controlled voltage source decreases when the output current of the controlled voltage source reaches the current limit. Bit line voltage V_{BL} decreases until it is equal to reference voltage V_{REF}, which indicates that the resistance of RRAM cell 120 has reached a target set resistance, described below with reference to FIG. 4. When bit line voltage V_{BL} is equal to reference voltage V_{REF}, comparison signal COMP output by voltage comparator 105 goes high. The high state of the comparison signal together with the high state of compare enable signal CMP_EN cause the output of enable gate 107 and, hence, inverse disable signal DIS_B output by disable circuit 102, to go low. The low state on the input of gate 103 causes the output of gate 103 to go low, which causes analog switch 104 to open. The open state of analog switch 104 disconnects bit line BL from the output of controlled voltage source 109. Once the bit line has been disconnected from controlled voltage source 109, bit line voltage V_{BL} falls further until it is approximately equal to source line voltage V_{SL} and remains at this voltage for the remainder of the write cycle.

A substantially zero voltage across RRAM cell 120 stops the set operation when the set resistance of the RRAM cell has fallen to a resistance that causes bit line voltage V_{BL} to fall to reference voltage V_{REF}. This set resistance is greater than the set resistance that RRAM cell 120 would have if the set voltage were applied through the entire write cycle. As noted above, the set resistance of RRAM cell depends on a defined operational mode of the RRAM cell.

In an example in which disable circuit 102 includes optional delay circuit 108, inverse disable signal DIS_B changes state a defined delay time t_{DLY} after the output of enable gate 107 changes state. During the delay time, RRAM cell 120 continues to be subject to the set operation. Consequently, the set resistance of the RRAM cell is less than a resistance that causes bit line voltage V_{BL} to fall to reference voltage V_{REF}, but is still greater than the set resistance that RRAM cell 120 would have if the set voltage were applied through the entire write cycle. Including delay circuit 108 allows RRAM cell 120 to be set to the slower set and reset times and longer data retention time mode of operation with voltage comparator 105 and reference voltage source 106 configured to detect the decrease in the bit line voltage that occurs when a conductive filament first establishes a conductive path in resistive element 121.

In the example shown in FIG. 2, disable circuit 102 operates only during a set operation. Compare enable signal CMP_EN is not asserted during a reset operation. This holds analog switch 104 closed throughout the reset operation.

In the example shown, RRAM device 100 operates in a single operational mode that provides a single combination of write performance and data retention time. Other embodiments operate in two or more operational modes, with each operational mode having a respective combination of write performance and data retention time. In some embodiments having two or more operational modes, disable circuit 102 changes the operational mode of RRAM device 100 automatically, e.g., in response to an external stimulus, or in response to a user command. In other embodiments having two or more operational modes, disable circuit 102 receives a mode control signal MC (FIG. 1) that defines the operational mode of the RRAM device. In an example, disable circuit 102 receives the mode control signal from a memory controller external to the RRAM device.

The operational mode of the example of RRAM device 100 shown in FIG. 2 may be changed by controlling reference voltage source 106 to generate a reference voltage V_{REF} appropriate for the operational mode in which the RRAM device is to operate. Increasing the reference voltage increases write performance and shortens the data retention time, whereas decreasing the reference voltage decreases write performance and lengthens the data retention time. In embodiments that include optional delay circuit 108, the operational mode of RRAM device 100 may be changed by controlling delay circuit 108 to provide a delay time T_{DLY} appropriate for the operational mode in which the RRAM device is to operate. Decreasing the delay time increases write performance and shortens data retention time, whereas increasing the delay time decreases write performance and lengthens data retention time. Delay circuit 108 may be controlled in addition to or instead of controlling voltage reference source 106.

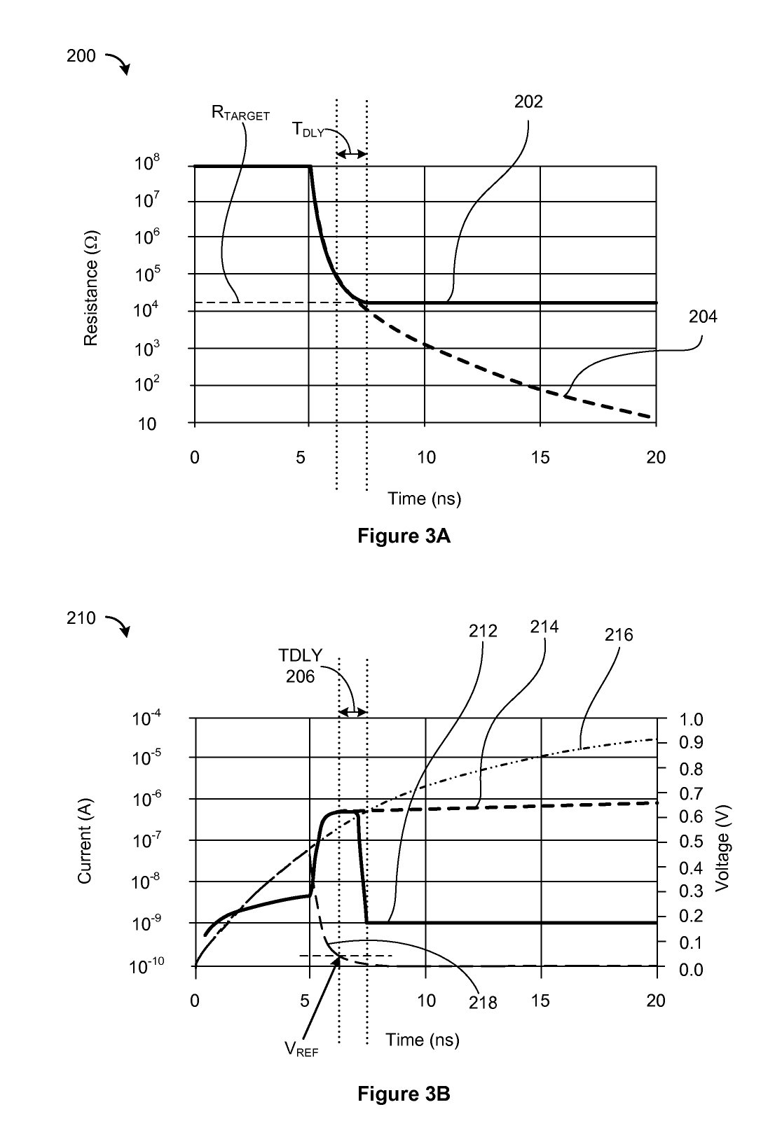

FIG. 3A is a resistance versus time graph showing an example of a three-terminal RRAM cell undergoing a set operation for two cases: (1) using a conventional write driver (broken line 204) and (2) using a write driver and disable circuit as disclosed herein (solid line 202). FIG. 3B is a current versus time graph showing the example of the RRAM cell undergoing the set operation for the same two cases: (1) using a conventional write driver (broken line 214), and (2) using a write driver and disable circuit as disclosed herein (solid line 212). FIG. 3B also shows a bit line voltage V_{BL} versus time graph for the same two cases (1) using a conventional write driver (dash-double-dot line 216) and (2) using a write driver and disable circuit as disclosed herein (dashed line 218). In the example shown, bit line voltage V_{BL} is measured relative to source line voltage V_{SL}.

Referring additionally to FIG. 2, in the set operation illustrated in FIGS. 3A and 3B, enable signal EN asserted at time t=0 ns causes controlled voltage source 109 to apply voltage V₁ to bit line BL. As a result, the bit line voltage V_{BL} (line 218) increases since RRAM cell 120 is in its high-resistance RESET state in which the RRAM cell has a resistance of about 10⁸ ohms, for example. After the set voltage has been applied to the RRAM cell for a time sufficient for conductive filaments to establish one or more conductive paths in the resistive element (about 5 ns in this example), the RRAM cell starts to transition to its low resistance SET state as indicated by solid line 202 in FIG. 3A. FIGS. 3A and 3B also show how, using the write driver described herein, as the resistance of the resistive element decreases (line 202), and the current through the RRAM cell increases (line 212) and bit line voltage V_{BL} (line 218) decreases. Disable circuit 102 detects when bit line voltage V_{BL} decreases to reference voltage V_{REF}. In the example shown in FIGS. 3A and 3B, disable circuit 102 includes optional delay circuit 108. Consequently, inverse disable signal DIS_B output by disable circuit 102 does not immediately change state when bit line voltage V_{BL} becomes equal to reference voltage V_{REF} to stop write driver 101 from continuing to apply voltage V₁ to bit line BL, but only does so after a delay time T_{DLY}. Disable circuit 102 outputting inverse disable signal DIS_B to write driver 101 causes the write driver to stop applying the set voltage to the bit line BL, which causes bit line current I_{BL} to drop to a low value (e.g., 10⁻⁹ A) (FIG. 3B, line 212), effectively stopping the set operation at the target resistance R_{TARGET} (e.g., about 10⁴ ohms in this example). Target resistance R_{TARGET} is less than the resistance that causes bit line voltage V_{BL} to fall below reference voltage V_{REF}. In contrast, the resistance of the RRAM cell controlled by a conventional write driver (broken line 204 in FIG. 3A) continues to decrease until enable signal EN turns write driver 101 off. As described above, continuing the set operation after RRAM cell 120 has been set to the SET state increases the time needed to perform a subsequent reset operation.

FIG. 4 graphically illustrates an example of the resistance ranges associated with the SET and RESET states of an example of RRAM cell 120, according to some embodiments. As shown in FIG. 4, the SET state of the RRAM cell is defined as any resistance of RRAM cell 120 less than or equal to a maximum set resistance 230. Thus, the SET state is associated with a range 234 of resistances of RRAM cell 120 less than or equal to maximum set resistance 230. Similarly, the RESET state is defined as any resistance of RRAM cell 120 greater than or equal to a minimum reset resistance 240. Minimum resistance 240 and associated range 244 of resistance values greater than or equal to minimum resistance 240 are shown in FIG. 4. In addition, the SET state of the RRAM cell has a target resistance 232 for the SET state, less than the maximum set resistance, to which the RRAM cell is set during a set operation. In embodiments in which disable circuit 102 additionally controls the reset operation, the RESET state of the RRAM cell has a target resistance 242 for the RESET state, greater than minimum reset resistance 240, to which the RRAM cell is set during a reset operation. The disable circuit 102 disables the write driver 101 when the resistance of the RRAM cell reaches the target resistance 232 for the SET state (and, optionally, when the resistance of the RRAM cell reaches the target resistance 242 for the RESET state) to which the RRAM cell is being changed. The values of the target resistances depend on the operational mode of the RRAM cell. The numeric resistances shown in FIG. 4 are merely examples; actual minimum, maximum and target resistances for a given RRAM cell may differ significantly from those illustrated in FIG. 4.

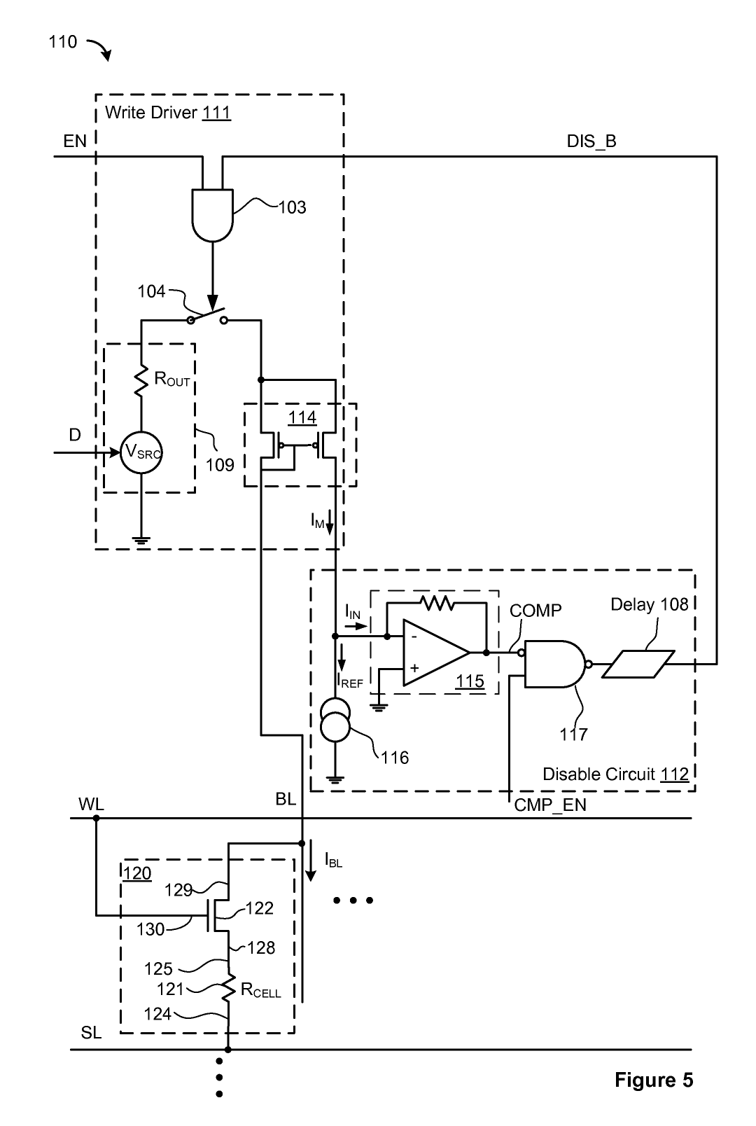

The example of disable circuit 102 shown in FIG. 2 senses bit line voltage V_{BL} on bit line BL to determine the condition of RRAM cell 120 at which to open analog switch 104 to disconnect the bit line from the output of controlled voltage source 109. In other embodiments, the disable circuit 102 senses a bit line current I_{BL} flowing through the bit line to determine when to open analog switch 104. FIG. 5 is a block diagram showing another example of an RRAM device 110 including a write driver 111 and a current-mode disable circuit 112, according to some embodiments. Write driver 111 is similar to the write driver 101 described above with reference to FIG. 2, but includes a current mirror circuit 114 interposed between analog switch 104 and bit line BL. Current mirror circuit 114 mirrors bit line current I_{BL} in bit line BL (i.e., the current through RRAM cell 120) to output to disable circuit 112 a mirror current I_{M} that has a defined ratio to bit line current I_{BL}. In an example, the ratio is 1:1.

Disable circuit 112 includes a reference current sink 116 connected to the output of current mirror circuit 114. Disable circuit 112 additionally includes a transimpedance amplifier 115, an enable gate 117 and optional delay circuit 108 connected in series between the output of current mirror circuit 114 and the output of the disable circuit. In the example shown, the input of enable gate 117 to which the output of transimpedance amplifier 115 is connected is an inverting input of enable gate 117. Compare enable signal CMP_EN is connected to another input of enable gate 117 and the output of enable gate 117 is connected to the input of optional delay circuit 108. In embodiments without delay circuit 108, the output of enable gate 117 provides disable signal DIS_B to one input of gate 103.

In the example shown in FIG. 5, a two-input NAND gate with one inverting input is used as enable gate 117. In other examples, another type of gate, an R-S latch, or another type of latch is used instead of enable gate 117.

Reference current sink 116 sinks a reference current I_{REF}. The difference between mirror current I_{M} and reference current I_{REF} provides an input current I_{IN} to transimpedance amplifier 115. Transimpedance amplifier 115 converts input current I_{IN} to an output voltage COMP with high gain, such that the transimpedance amplifier can be regarded as being a comparator having an output in a low state when input current I_{IN} is positive (i.e., I_{M}(=I_{BL})>I_{REF}) and having an output in a high state when input current I_{IN} is negative (i.e., I_{M}(=I_{BL})<I_{REF}).

Operation of RRAM device 110 is similar to that of RRAM device 100 described above with reference to FIG. 2. Prior to a set operation, word line WL is driven to a high voltage and data signal D in its high state causes controlled voltage source 109 to generate a nominal output voltage equal to the voltage V₁ of RRAM cell 120, i.e., V_{SRC}=V₁ during the set operation. Additionally, reference current sink 116 sinks reference current I_{REF} at a level appropriate for a set operation, e.g., a current corresponding to the target resistance of RRAM cell 120. Enable signal EN is a low state that holds the output of gate 103 in a low state. The low output state of gate 103 holds analog switch 104 open. Consequently, no bit line current I_{BL} flows in bit line BL, no mirror current I_{M} is output from current mirror circuit 114, and transimpedance amplifier 115 outputs comparison signal COMP in a high state. The inverting input of enable gate 117 inverts the high state of comparison signal COMP to a low state. Moreover, compare enable signal CMP_EN is also in a low state. Consequently, the output of enable gate 117 in a high state, and disable circuit 102 outputs disable signal DIS_B in a high state.

At the start of the set operation, enable signal EN goes high, but compare enable signal CMP_EN remains low. The high state of enable signal EN causes the output of gate 103 to go high, since disable signal DIS_B on the other input of the gate is also high. The high state of the output of gate 103 causes analog switch 104 to close. In its closed state, analog switch 104 applies the nominal output voltage V_{SRC} of controlled voltage source 109 to bit line BL and bit line voltage V_{BL} rises towards the voltage V₁ output by the controlled voltage source 109. Since RRAM cell 120 is initially in its high-resistance RESET state, bit line current I_{BL}, and, hence, mirror current I_{M}, are less than reference current I_{REF}, the comparison signal COMP output by transimpedance amplifier 115 remains high, and disable signal DIS_B output by voltage comparator 105 remains in a high state so that analog switch 104 remains closed. Compare enable signal CMP_EN is then asserted (goes high) at a time prior to the earliest time RRAM cell 120 can change to its SET state in response to the set voltage. However, the high state of comparison signal COMP holds the output of enable gate 117, and, hence, disable signal DIS_B, high, and analog switch 104 remains closed.

Application of the set voltage to bit line BL causes RRAM cell 120 to undergo a set operation. When the set voltage has been applied for a time sufficient for a conductive filament to establish a conductive path in the resistive element 121 of the RRAM cell, the resistance of RRAM cell 120 decreases. As the resistance of the RRAM cell decreases, bit line current I_{BL}, and, hence, mirror current I_{M}, increase. Once bit line current I_{BL}, and, hence, mirror current I_{M}, exceed reference current I_{REF}, which indicates that the resistance of RRAM cell 120 has reached the target set resistance, comparison signal COMP output by transimpedance amplifier 115 goes low. The inverting input of enable gate 117 inverts the low state of the compare signal to a high state that causes the output of enable gate 117, and, hence disable signal DIS_B output by disable circuit 112, to go low. The low state on the input of gate 103 causes the output of gate 103 to go low, which causes analog switch 104 to open. The open state of analog switch 104 disconnects bit line BL from the output of controlled voltage source 109. Once the bit line has been disconnected from controlled voltage source 109, the bit line current falls substantially to zero, which stops the set operation. Additionally, the bit line voltage falls until it is approximately equal to source line voltage V_{SL} and remains at this voltage for the remainder of the write cycle.

When the bit line current I_{BL} falls below I_{REF}, comparison signal COMP goes low, which would cause the disable signal DIS_B generated by enable gate 117 to go high. This would cause the bit line BL to be reconnected to the controlled voltage source 109. However, additional circuitry (not shown) may be provided to operate in response to the fall in the bit line voltage to deassert the compare enable signal CMP_EN. Compare enable signal CMP_EN in its low state holds disable signal DIS_B low and prevents reconnection of bit line BL to controlled voltage source 109. Alternatively, an R-S latch or another suitable type of latch may be substituted for enable gate 117. The latch drives the disable signal DIS_B low when comparison signal COMP changes state as the RRAM cell reaches its target set resistance and holds disable signal DIS_B low for the remainder of the write cycle notwithstanding subsequent changes in the state of comparison signal COMP.

Substantially no bit line current I_{BL} flowing through RRAM cell 120 stops the set operation when the set resistance of the RRAM cell has fallen to a resistance that causes the bit line current to exceed reference current I_{REF}. This set resistance is greater than the set resistance that RRAM cell 120 would have if the set voltage were applied through the entire write cycle. As noted above, the set resistance of RRAM cell depends on a defined operational mode of the RRAM cell.

Since current mirror circuit 114 does not conduct in the reverse direction, as would occur during a reset operation, write driver 111 additionally includes a switch (not shown) connected in parallel with the current mirror. The switch is controlled by an inverter (not shown) that inverts data signal D to turn on the switch when the data signal is in its 0 state, corresponding to a reset operation. Turning on the switch by-passes the current mirror.

The example of RRAM device 110 shown in FIG. 5 operates in a single operational mode that provides a single combination of write performance and data retention time. Other embodiments operate in two or more operational modes, with each operational mode having a respective combination of write performance and data retention time. In some embodiments having two or more operational modes, disable circuit 112 changes the operational mode of RRAM device 110 automatically, e.g., in response to an external stimulus, or in response to a user command. In other embodiments having two or more operational modes, disable circuit 112 receives a mode control signal MC (FIG. 1) that defines the operational mode of the RRAM device. In an example, disable circuit 112 receives the mode control signal from a memory controller external to the RRAM device.

In some implementations, the operational mode of the example of RRAM device 110 shown in FIG. 5 is changed by controlling reference current sink 116 to sink a reference current I_{REF} corresponding to the operational mode in which the RRAM device is to operate. Increasing the reference current increases write performance and shortens data retention time, whereas decreasing the reference current decreases write performance and lengthens data retention time. In embodiments that include optional delay circuit 108, the operational mode of RRAM device 100 is additionally or alternatively changed by controlling delay circuit 108 to provide a delay time T_{DLY} corresponding to the operational mode in which the RRAM device is to operate, as described above with reference to FIG. 2.

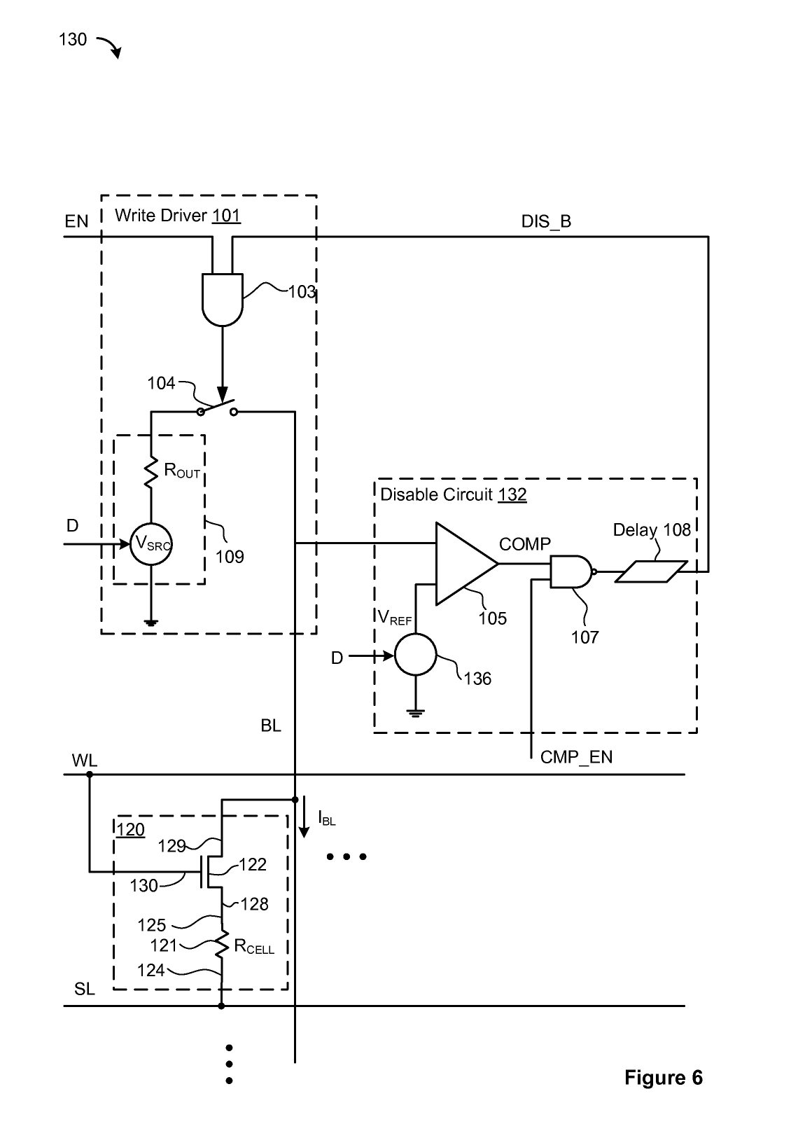

In some embodiments, the disable circuit is additionally configured to control the write driver 101 to define the resistance of RRAM cell 120 during a reset operation. FIG. 6 is a block diagram showing an example of an RRAM device 130 having above-described write driver 101 and a disable circuit 132 configured to control the write driver 101 to define the resistance of RRAM cell 120 during both a set operation and a reset operation performed by write driver 101.

Disable circuit 132 is similar in structure and operation to disable circuit 102 described above with reference to FIG. 2, but differs in that a reference voltage source 136 connected to voltage comparator 105 is configured to generate different reference voltages V_{REF} depending on the state of data signal D input to the reference voltage source. When data signal D is in its high state, indicating a set operation, reference voltage source 136 generates a set-mode reference voltage V_{REF1} corresponding to the target resistance for the SET state (232 in FIG. 4) of RRAM cell 120. When data signal D is in its low state, indicating a reset operation, reference voltage source 136 generates a reset-mode reference voltage V_{REF0} corresponding to the target resistance for the RESET state (242 in FIG. 4) of RRAM cell 120.

During a set operation, in response to data signal D in its 1 state, controlled voltage source 109 generates a nominal output voltage equal to the voltage V₁ of RRAM cell 120, and reference voltage source 136 outputs a set-mode reference voltage V_{REF1} (V₁>V_{REF1}>V_{SL}) appropriate for the set operation. Operation of disable circuit 132 during the set operation is similar to that of disable circuit 102 described above with reference to FIG. 2.

Prior to a reset operation, RRAM cell 120 is in its low-resistance SET state. Data signal D is supplied to RRAM device 130 in its 0 state. Data signal D in its 0 state causes controlled voltage source 109 to generate a nominal output voltage equal to voltage V₃, i.e., V_{SRC}=V₃ during the reset operation. Typically, V_{SRC} is 0 V during the reset operation. Data signal D in its 0 state also causes reference voltage source 136 to output a reset-mode reference voltage V_{REF0} (V₃<V_{REF0}<V_{SL}) appropriate for the reset operation. Enable signal EN is in a low state that holds the output of gate 103 in a low state. The low output state of gate 103 holds analog switch 104 open. With the analog switch 104 open, the voltage V_{BL} on bit line BL is nominally equal to source line voltage V_{SL}. Since bit line voltage V_{BL} is greater than reference voltage V_{REF}, voltage comparator 105 outputs comparison signal COMP in a low state. However, since compare enable signal CMP_EN is in a low state, which holds the output of enable gate 107 in a high state, disable circuit 132 outputs disable signal DIS_B in a high state.

At the start of the reset operation, enable signal EN goes high, but compare enable signal CMP_EN remains low and disable signal DIS_B remains high. The high state of enable signal EN causes the output of gate 103 to go high, since disable signal DIS_B on the other input of the gate is also high. The high state of the output of gate 103 causes analog switch 104 to close. In its closed state, analog switch 104 applies the nominal output voltage V_{SRC} of controlled voltage source 109 to bit line BL, but the low resistance of RRAM cell 120 in its set state holds bit line voltage V_{BL} to a value dependent on R_{OUT}. As a result, the comparison signal COMP output by voltage comparator 105 remains in a low state. Moreover, compare enable signal CMP_EN is also low, so that the output of enable gate 107 and, hence, disable signal DIS_B remain high, and analog switch 104 remains closed.

Compare enable signal CMP_EN is then asserted (goes high) at a time prior to the earliest time that RRAM cell 120 can change to its RESET state in response to the reset voltage. However, the low state of comparison signal COMP holds the output of enable gate 107, and, hence, disable signal DIS, high, and analog switch 104 remains closed.

Application of the reset voltage to bit line BL causes RRAM cell 120 to undergo a reset operation. When the reset voltage has been applied for a time sufficient to break the last conductive path in the resistive element 121 of the RRAM cell, the resistance of RRAM cell 120 increases. As the resistance of the RRAM cell increases, bit line voltage V_{BL} decreases towards the nominal RESET output voltage of controlled voltage source 109 as bit line current I_{BL} decreases and the voltage drop across the output resistance R_{OUT} of the controlled voltage source decreases. Bit line voltage V_{BL} decreases until it is less than reset-mode reference voltage V_{REF0}, which indicates that the resistance of RRAM cell 120 has reached target reset resistance 242, described above with reference to FIG. 4. When bit line voltage V_{BL} decreases below reset-mode reference voltage V_{REF0}, comparison signal COMP output by voltage comparator 105 goes high. The high state of the comparison signal together with the high state of compare enable signal CMP_EN cause the output of enable gate 107 and, hence, inverse disable signal DIS_B output by disable circuit 112, to go low. The low state on the input of gate 103 causes the output of gate 103 to go low, which causes analog switch 104 to open. The open state of analog switch 104 disconnects bit line BL from the output of controlled voltage source 109. Once the bit line BL has been disconnected from controlled voltage source 109, bit line voltage V_{BL} rises until it is approximately equal to source line voltage V_{SL} and remains at this voltage for the remainder of the write cycle.

When the bit line voltage V_{BL} falls below V_{REF0}, the inverse disable signal DIS_B generated by the enable gate 107 returns to its high state, which causes the gate 103 and the analog switch 104 to reconnect bit line BL to the controlled voltage source 109. To prevent the controlled voltage source 109 from being repeatedly connected to and disconnected from the bit line BL as the bit line voltage V_{BL} repeatedly becomes greater than and less than the reference current V_{REF0}, additional circuitry (not shown) may be provided to operate in response to the fall in the bit line voltage to deassert the compare enable signal CMP_EN. Compare enable signal CMP_EN in its low state holds the inverse disable signal DIS_B low and prevents reconnection of bit line BL to controlled voltage source 109. Alternatively, an R-S latch or another suitable type of latch (not shown) may be substituted for enable gate 107. The latch drives the inverse disable signal DIS_B low when comparison signal COMP changes state as the RRAM cell reaches its target reset resistance and holds inverse disable signal DIS_B low for the remainder of the write cycle notwithstanding subsequent changes in the state of comparison signal COMP.

A substantially zero voltage across RRAM cell 120 stops the reset operation when the set resistance of the RRAM cell has increased to a resistance that causes bit line voltage V_{BL} to decrease below reset-mode reference voltage V_{REF0}. This reset resistance is less than the reset resistance that RRAM cell 120 would have if the reset voltage were applied through the entire write cycle. As noted above, the reset resistance of RRAM cell depends on a defined operational mode of the RRAM cell.

In an example in which disable circuit 132 includes optional delay circuit 108, disable signal DIS_B changes state a defined delay time t_{DLY} after the output of enable gate 107 changes state. During the delay time, RRAM cell 120 continues to be subject to the reset operation. Consequently, the reset resistance of the RRAM cell is greater than the resistance that causes bit line voltage V_{BL} to fall below reset-mode reference voltage V_{REF0}, but is still less than the reset resistance that RRAM cell 120 would have if the reset voltage were applied through the entire write cycle. Including delay circuit 108 allows RRAM cell 120 to be set to the slower set and reset times and longer data retention time mode of operation with voltage comparator 105 and reference voltage source 106 configured to detect the decrease in the bit line voltage that occurs when the last conductive filament breaks in resistive element 121.

In the example shown in FIG. 6, RRAM device 130 operates in a single operational mode that provides a single combination of write performance and data retention time. Other embodiments operate in more than one operational mode, with each operational mode having a respective combination of write performance and data retention time. In some embodiments having two or more operational modes, disable circuit 132 changes the operational mode of RRAM device 130 automatically, e.g., in response to an external stimulus, or in response to a user command. In other embodiments having two or more operational modes, disable circuit 132 receives a mode control signal MC (FIG. 1) that defines the operational mode of the RRAM device. In an example, disable circuit 132 receives the mode control signal from a memory controller external to the RRAM device.

The operational mode of the example of RRAM device 130 shown in FIG. 6 may be changed by controlling reference voltage source 136 in disable circuit 132 to generate respective reference voltages, e.g., V_{REF0} and V_{REF1} corresponding to the operational modes in which the RRAM device is to operate. Increasing the reference voltage produced by reference voltage source 136 increases write performance and shortens the data retention time, whereas decreasing the reference voltage produced by reference voltage source 136 decreases write performance and lengthens the data retention time. In embodiments that include optional delay circuit 108, the operational mode of RRAM device 130 additionally or alternatively controls delay circuit 108 to provide a delay time T_{DLY} that corresponds to the operational mode in which the RRAM device is to operate, as described above with reference to FIG. 2.

Current-mode RRAM device 110 described above with reference to FIG. 5 may be modified to include disable circuits, similar to current-mode disable circuit 112, that operate during a set operation and a reset operation, respectively. In such an embodiment, the set-operation disable circuit includes a reference current sink that sinks a relatively large reference current, and the reset-operation disable circuit includes a reference current source that sources a relatively small reference current. In either case, the reference current depends on the target resistance of the resistive element in the respective write operation, and the voltage across the RRAM cell during the write operation. As mentioned above, in some examples, the set target resistance in the SET state is defined by a range of resistances having a maximum resistance at the maximum resistance of RRAM cell 120 in the SET state and the target resistance in the RESET state is defined by a range of resistances having a minimum resistance at the minimum resistance of the RRAM cell in the RESET state. Thus, the memory operation being performed is associated with a range of resistance values of RRAM cell 120. Accordingly, in some embodiments, the value of reference current I_{REF} is determined based on the write operation being performed and a target resistance of the RRAM cell within the range of resistance values associated with the write operation being performed. In some embodiments, the target resistance value for a SET operation is less than the maximum resistance of the RRAM cell in the SET state, and the target resistance value for a RESET operation is more than the minimum resistance of the RRAM cell in the RESET state.

In some embodiments, disable circuits 102, 112, 132 are integral with write drivers 101, 111 and 101, respectively.

In some embodiments, the resistance to which RRAM cell 120 is set during a write operation is controlled by controlling the pulse width of enable signal EN. Instead of using the disable circuit shown in FIG. 1, 2 5 or 6, the pulse width of enable signal EN depends on the target resistance of RRAM cell 120. For example, in a set operation, an enable signal EN having a shorter pulse width is used when the RRAM cell is to be written to in a way that results in faster write performance and a shorter data retention time (e.g., a “volatile” mode of operation of RRAM cell 120). In contrast, an enable signal EN having a longer pulse width is used when the RRAM cell is to be written to in a way that results in slower write performance and a longer data retention time (e.g., a “non-volatile mode” of operation of RRAM cell 120). Additionally or alternatively, the pulse width of the control signal applied to word line WL can be controlled to control the mode of operation of the RRAM cell 120.

In the examples described above with reference to FIGS. 1, 2, 5 and 6, a write signal applied to bit line BL is controlled to control the resistance of RRAM cell 120. However, in other examples, the resistance of the RRAM cell 120 is controlled by controlling the source line voltage V_{SL} on the source line SL of the RRAM cell 120. For example, when the RRAM cell 120 reaches a desired resistance, the source line voltage V_{SL} is set to a value that disables the write operation being performed on the RRAM cell 120. In these examples, the source lines SL in the RRAM device 300 are configured so the source lines SL run parallel to the bit lines BL. Furthermore, there may be one source line for each bit line or one source line for multiple bit lines. Alternatively, in some implementations, the write operation is controlled by setting the word line voltage, which determines a current limit through gate device 122. The write operation stops when the current limit is reached, which determines the voltage across the RRAM cell 120 at the end of the write operation. In these implementations, different word line voltage levels are used to control the mode of operation of the RRAM cells being written. For example, one word line voltage level is associated with a “volatile” mode of operation of RRAM cell 120, while another word line voltage level is associated with a “non-volatile mode” of operation of RRAM cell 120.

As described above, by controlling the set operation, e.g., by controlling the time during which the write driver applies a set voltage to the bit line, or discontinuing the set operation when a defined condition exists on the bit line, the set resistance of the RRAM cell may be set to a target set resistance. The set resistance of the RRAM cell in turn defines the data retention characteristic of the RRAM cell. For example, faster write performance is obtained by discontinuing the write operation in response to sensing a decrease in the resistance of the RRAM cell. The faster write performance is obtained at the expense of a shorter data retention time since the RRAM cell is more likely to revert spontaneously to the RESET state. In contrast, a slower write operation that results in a longer data retention time (i.e., the RRAM cell is less likely to revert to the RESET state) is obtained by discontinuing the write operation in response to sensing that the resistance of the RRAM cell has reached a defined low value. An RRAM device described below utilizes this control over write behavior to operate in different modes.

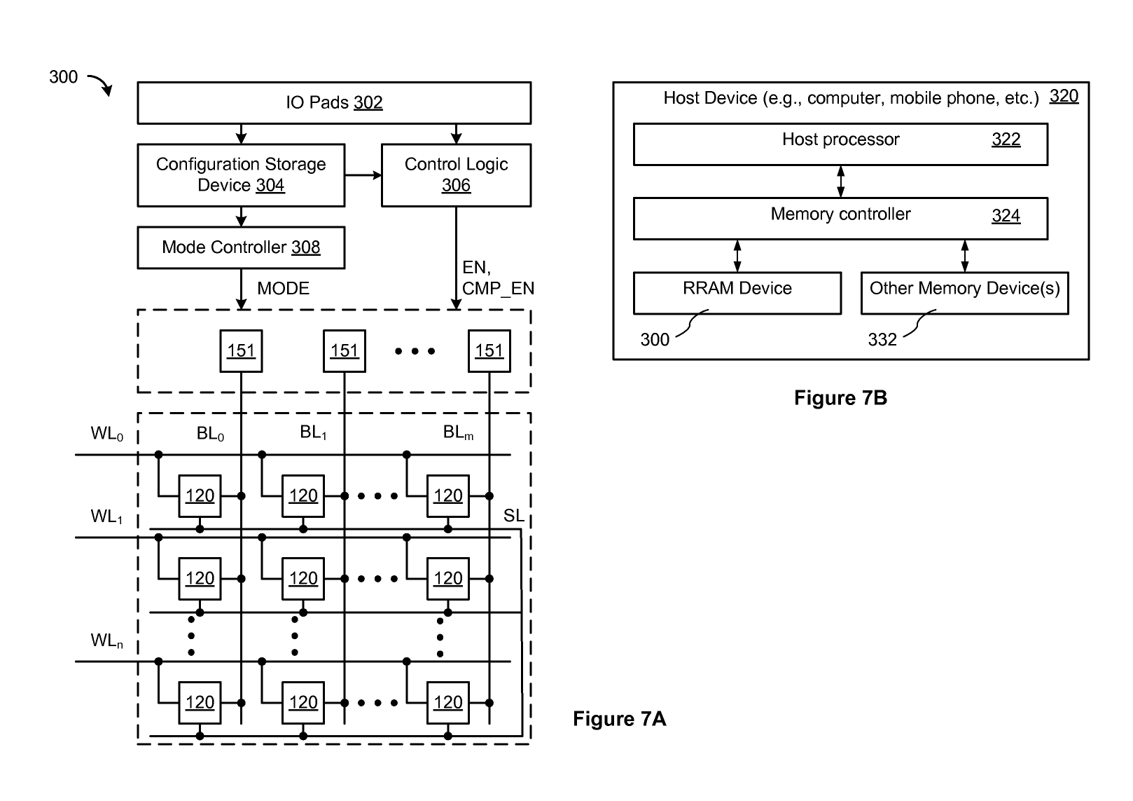

FIG. 7A is a block diagram showing an example of an RRAM device 300. FIG. 7B is a block diagram showing an example a host device 320 that includes RRAM device 300. RRAM device 300 includes an array (e.g., a two-dimensional array, or a three-dimensional array) of RRAM cells 120 that can be operated in two or more different modes of operation. In this embodiment, each mode of operation has a different combination of write performance and data retention time, as described below. The RRAM device 300 includes IO pads 302, a configuration storage device 304, control logic 306, a mode controller 308, controlled write drivers 151, RRAM cells 120, bit lines BL₀, BL₁, . . . , BLₘ and word lines WL₀, WL₁, . . . , WLₙ. Each of the controlled write drivers 151 includes a write driver (e.g., write driver 101, or write driver 111) and a suitable disable circuit (e.g., disable circuit 102, disable circuit 112 or disable circuit 132). In the example shown, each controlled write driver 151 is coupled to a respective one of bit lines BL₀, BL₁, . . . , BLₘ. In other examples, each controlled write driver 151 is shared between two or more of the bit lines using, for example, a multiplexer (not shown). Each bit line BL₀, BL₁, . . . , BLₘ is coupled to one or more RRAM cells 120. Typically, each bit line is coupled to n RRAM cells, one RRAM cell 120 for each of the word lines WL₀, WL₁, . . . , WLₙ, so that each RRAM cell 120 is coupled to a respective bit line BL₀, BL₁, . . . , BLₘ and a respective word line WL₀, WL₁, . . . , or WLₙ.

In addition to RRAM device 300, host device 320 includes a host processor 322 and a memory controller 324 coupled to host processor 322. RRAM device 300 and, optionally, one or more additional memory devices 332 are coupled to memory controller 324. In RRAM device 300, IO pads 302 receive data and commands from memory controller 324. IO pads 302 are also used to convey data read from RRAM cells 120 to memory controller 324. Configuration storage device 304 stores write driver settings and timing control settings corresponding to different modes of operation of RRAM device 300. The write driver settings include values of the reference voltage V_{REF} (or reference current I_{REF}) and/or delay time T_{DLY} used in the disable circuit included in or that controls each controlled write driver 151 or in the disable circuits (e.g., disable circuit 102, 112 or 132) included in (or coupled to) a set of write drivers.

In some embodiments, RRAM device 300 has two modes of operation. A first mode is a faster write performance and shorter data retention time mode, and is referred to herein as a “volatile mode of operation.” A second mode is a slower write performance and longer data retention time mode, and is referred to herein as a “non-volatile mode of operation.” In other embodiments, RRAM device 300 has three or more different modes of operation, each having a different combination of write performance and data retention time. Configuration storage device 304 can be implemented as a register, a fuse, a bond option, or a metal option. In some embodiments, the mode of operation of at least a subset of the RRAM cells 120 in RRAM device 300 is not user programmable. For example, the mode of operation for the RRAM cells whose mode of operation is not user-programmable may be set using fuses, metal options, bonding options, a read-only register, an internal non-volatile storage device, or an external non-volatile storage device (e.g., a flash memory device). In some embodiments, when the RRAM device 300 includes more than one mode of operation, the RRAM device 300 is partitioned so that a subset of the RRAM cells of the RRAM device 300 are used to store memory device configuration information (or settings), where the subset of the RRAM cells operates in a first mode of operation (e.g., a non-volatile mode of operation), while the rest of the RRAM cells operate in at least one other mode of operation.

Control logic 306 generates enable signal EN (see also FIGS. 1, 2, 5 and 6) to enable controlled write drivers 151 and compare enable signal CMP_EN to enable the comparison performed by the disable circuit in each controlled write driver. In some embodiments, control logic 306 includes one or more state machines for carrying out the sequences of internal operations to perform memory operations corresponding to commands received from memory controller 324. In some embodiments, control logic 306 includes one or more state machines for rewriting data to a respective RRAM cell when the mode of operation of the cell changes (e.g., from a volatile mode of operation to a non-volatile mode of operation, or vice-versa).

Mode controller 308 receives data from configuration storage device 304 and, in response thereto, generates what will be referred to herein as MODE signals that control the operation of the disable circuit in each of the controlled write drivers 151. In an example, the MODE signal defines the reference voltage V_{REF} generated by reference voltage source 106 described above with reference to FIG. 2 or the reference voltages V_{REF0} and V_{REF1} generated by reference voltage source 136 described above with reference to FIG. 6. In another example, the MODE signal defines the reference current I_{REF} generated by reference current sink 116 described above with reference to FIG. 5. In another example, reference voltage sources 106 and 136 are omitted from disable circuits 102 and 132, respectively, described above with reference to FIGS. 2 and 6, respectively, and mode controller 308 supplies reference voltage V_{REF} or reference voltages V_{REF0} and V_{REF1} directly to the disable circuits of one or more of controlled write drivers 151 as a MODE signal. In yet another example, the MODE signal defines the delay time T_{DLY} provided by optional delay circuit 108 described above with reference to FIGS. 2, 5 and 6 in addition to or instead of the above described reference voltage or current definitions, or reference voltage.

In some embodiments, the MODE signal generated by mode controller 308 defines a reference voltage V_{REF}, a reference current I_{REF}, or a delay time T_{DLY}, or provides one or more reference voltages for each type of memory operation being concurrently performed in the RRAM device 300. In an example, set operations are performed on a first set of the RRAM cells 120 on the word line WL0 and reset operations are performed on a second set of the RRAM cells 120 on the word line WL0. In an example, mode controller 308 concurrently generates a MODE signal that defines a first reference voltage V_{REF}, or a first reference current I_{REF}, and/or a first delay time T_{DLY} for the set operations and generates a MODE signal that defines a second reference voltage V_{REF}, or a second reference current I_{REF}, and/or a second delay time T_{DLY} for the reset operations (or provides one or more reference voltages directly).

In some embodiments, data and commands are received directly from, and read-out data is provided directly to, host processor 322. In this case, the above-described functions of memory controller 324 are performed by the host processor and memory controller 324 is omitted.

An exemplary memory operation in RRAM device 300 will now be described. Data and commands are received on IO pads 302 and instruct control logic 306 to perform particular memory operations. In an example, a received command (e.g., a write command) and data (e.g., a multi-bit value that includes both 1s and 0s) instructs control logic 306 to perform a set operation on a first set of the RRAM cells 120 on word line WL₀, and concurrently to perform a reset operation on a second set of the RRAM cells on word line WL₀. Write driver settings (e.g., enable signal EN and compare enable signal CMP_EN) and the values of the reference voltage(s) V_{REF}, or reference currents I_{REF}, and/or delay time T_{DLY} corresponding to the memory operations are obtained from configuration storage device 304. In response to the reference voltage, or reference current, and/or delay time values obtained from configuration storage device 304, mode controller 308 generates MODE signals and supplies a MODE signal to each controlled write driver 151. The controlled write drivers then perform the memory operations based on the write driver settings and the MODE signals.

In some implementations, the RRAM device 300 includes a memory controller (not shown). In these implementations, IO pads 302 are coupled to the memory controller of the RRAM device 300, which in turn is coupled to configuration and storage device 304 and control logic 306.

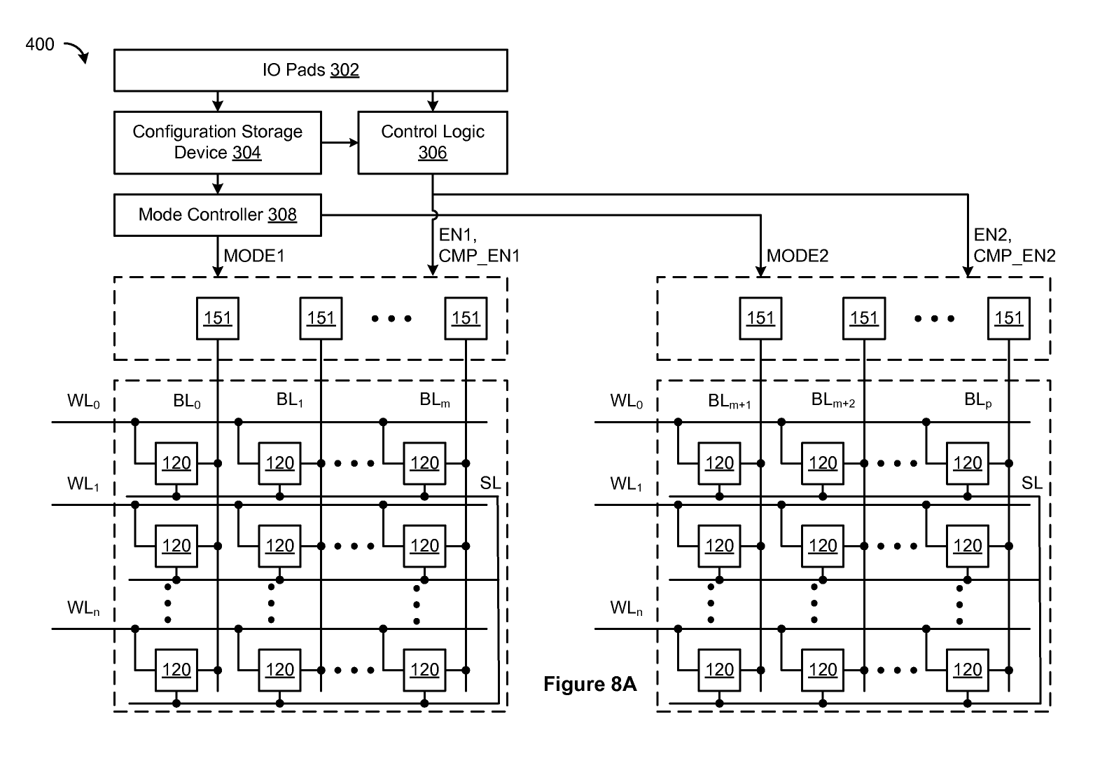

The exemplary host device 320 shown in FIG. 7B is a computer system or other electronic device, such as a mobile phone, a smart phone, or cell phone, a personal digital assistant or another electronic device that includes a memory device and a memory controller coupled between the memory device and host processor 322. Host device 320 includes an RRAM device 300 (FIG. 7A), 400 (FIG. 8A) or 420 (FIG. 8B) in which memory operations are performed. The example of host device 320 shown includes a memory controller 324 that receives commands from host processor 322 and provides memory operation commands to RRAM device 300. Optionally, memory controller 324 additionally provides memory operation commands to one or more other memory devices 332. Alternatively, as noted above, host processor 322 communicates commands and data directly to RRAM device 300 and, optionally, one or more other memory devices 332.

FIG. 8A is a block diagram showing an example of an RRAM device 400 in which subsets of the RRAM cells in the RRAM device are operated in different modes of operation. Since RRAM device 400 is similar to RRAM device 300 described above with reference to FIG. 7, only the differences are discussed. In the example shown in FIG. 8A, control logic 306 generates two sets of enable signals EN1 and EN2, two sets of compare enable signals CMP_EN1 and CMP_EN2, and two sets of mode control signals MODE1 and MODE2 to operate a first set of the RRAM cells 120 on bit lines BL₀, BL₁, . . . , BLₘ in a first mode of operation and to operate a second set of RRAM cells 120 on bit lines BLₘ₊₁, BLₘ₊₂, . . . , BLₚ in a second mode of operation. In some implementations, control logic 306 generates a single set of enable signals and compare enable signals that is used in the write operations performed on both the first and second sets of RRAM cells 120.

In one example, the first mode of operation for the first set of RRAM cells 120 is a non-volatile mode of operation (longer data retention time and slower write performance), whereas the second mode of operation for the second set of RRAM cells 120 is a volatile mode of operation (shorter data retention time and faster write performance). In an example, the first set of the RRAM cells 120 is used to store system configuration information and/or memory device configuration information, which typically needs to have a longer data retention time, and the second set of the RRAM cells 120 is used to store data for which volatility is not a concern. The second set of RRAM cells 120 is refreshed periodically during normal operation and/or reloaded from non-volatile memory (e.g., a hard disk, flash memory, etc.) when the system is powered up.

In the example of an RRAM device 420 shown in FIG. 8B, separate and distinct mode controllers 308 are used to generate mode signals MODE1 and MODE2 for the first set of RRAM cells 120 and the second set of RRAM cells 120, respectively.

In some embodiments, the characteristics (e.g., volatility, data retention time, etc.) of each set of RRAM cells 120 are configurable by a mode register (e.g., a register in configuration storage device 304). Alternatively, the characteristics of each set of RRAM cells are configurable at the time of manufacturing or post-manufacturing testing by using fuses, metal masks, metal options, and/or internal or external non-volatile memory.

In some embodiments, the RRAM cells (e.g., the rows and/or columns of RRAM cells) in each set of RRAM cells 120 are configurable. In some implementations, the RRAM cells in each set of RRAM cells 120 are configured during manufacturing. In some implementations, the RRAM cells in each set of RRAM cells 120 are configured during initialization of the RRAM device 420 by a system including the RRAM device 420. In some implementations, the RRAM cells in each set of RRAM cells 120 are configured during operation of the RRAM device 420 by a system including the RRAM device 420.

### Operating an RRAM Device

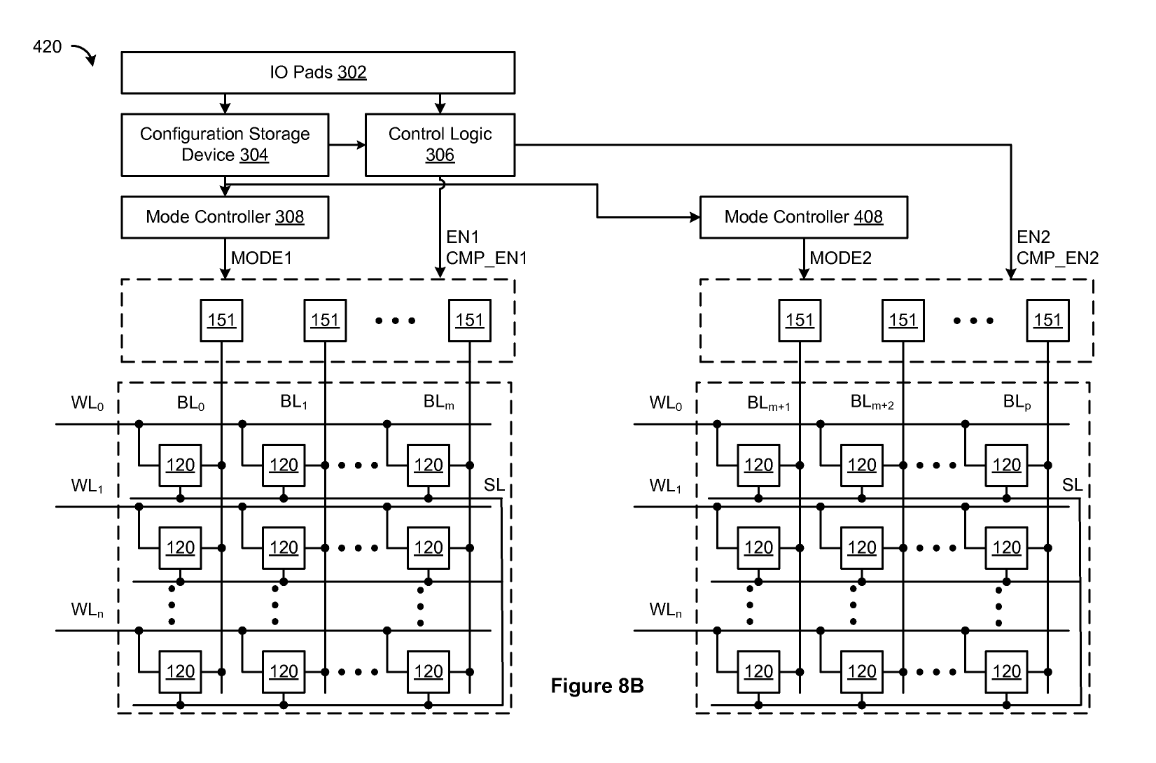

FIG. 9 is a flowchart showing an example of a method 500 for operating an RRAM device. The operations described below are performed by the RRAM device, which includes a controlled write driver for a bit line BL coupled to an RRAM cell 120. The controlled write driver includes a write driver (e.g., write driver 101 or write driver 111) controlled by a disable circuit (e.g., disable circuit 102, disable circuit 112 or disable circuit 132). Embodiments of method 500 may be applied to any of the RRAM device embodiments described above with reference to FIGS. 1, 2, 6, 7A, 8A and 8B.

In block 502, the RRAM device accesses or otherwise obtains a controlled write driver setting for a mode of operation of the RRAM cell. The write driver setting defines operation of the controlled write driver in the mode of operation of operation of the RRAM cell. The write driver setting is one of a number of distinct write driver settings, or sets of write driver settings, for defining operation of the controlled write driver in a corresponding number of modes of operation of the RRAM cell. In some embodiments, each of the modes of operation corresponds to a distinct characteristic data retention time of the RRAM cell. In some implementations, the distinct characteristic data retention times are in substantially non-overlapping data retention time ranges. In an example, a “volatile” mode of operation has a data retention time on the order of milliseconds to seconds and a “non-volatile” mode of operation has a data retention time on the order of years. The actual data retention times of the respective modes of operation may be set using (or defined based on) a system that includes the RRAM device.

Typically, when the RRAM cell is operating in the volatile mode of operation, the RRAM cell has faster write performance and a shorter data retention time than when the RRAM cell is operating in the non-volatile mode of operation. Typically, when the RRAM cell is operating in the volatile mode of operation, the resistance of the RRAM cell in the SET state is higher than the resistance of the RRAM cell when operating in the non-volatile mode of operation and the RRAM cell is in the SET state.

In some embodiments, the RRAM device includes control logic 306 that, in conjunction with controlled write driver 151, rewrites data stored in the RRAM cell when the mode of operation of the RRAM cell is changed from the volatile mode of operation to the non-volatile mode of operation. In this example, the data is rewritten with the RRAM cell operating in the non-volatile mode of operation to make the data non-volatile. In some embodiments, control logic 306 and controlled write driver 151 rewrite the data stored in the RRAM cell during a refresh operation. In some implementations, the refresh operation is a self-refresh operation performed periodically by the RRAM device to refresh RRAM cells when the RRAM cells are operating in a volatile mode of operation. In some implementations, the refresh operation is initiated by an external refresh command received by the RRAM device.

Similarly, in some embodiments, control logic 306, in conjunction with controlled write driver 101, rewrites data stored in the RRAM cell when the mode of operation of the RRAM cell is changed from the non-volatile mode of operation to the volatile mode of operation. In this example, the data is rewritten so that it can be quickly overwritten, if needed. In the volatile mode of operation, write times are relatively short, and the shorter write times would not be sufficient to overwrite data that had been written while the RRAM cell was operating in the non-volatile operating mode. Again, in some embodiments, control logic 306, write driver 101 and disable circuit 102 rewrite the data stored in the RRAM cell during a refresh operation. In some implementations, the refresh operation is a self-refresh operation performed periodically by the RRAM device to refresh RRAM cells in a volatile mode of operation. In some implementations, the refresh operation is initiated by an external refresh command received by the RRAM device.

Next, in block 504, the RRAM device performs a write operation on RRAM cell 120 in accordance with the write driver setting for a mode of operation of the RRAM cell. The write driver setting is one of a number of distinct write driver settings for controlling operation of the controlled write driver in a corresponding number of modes of operation of the RRAM cell.

In block 506, controlled write driver 151 stops performing the write operation on the RRAM cell 120 when a predefined condition is achieved on the bit line. The predefined condition depends on the mode of operation of the RRAM cell 120. In some embodiments, the predefined condition on the bit line corresponds to a predefined SET state condition of the RRAM cell. In some embodiments, the predefined SET state condition is based on a resistance of the RRAM cell.

In some embodiments, a current sufficient to reset the RRAM cell to the RESET state in a defined time while operating in the non-volatile mode of operation is higher than a current sufficient to reset the RRAM cell to the RESET in the defined time while operating in the volatile mode of operation.

In some embodiments, a time sufficient to reset the RRAM cell to the RESET state using a defined current while operating in the non-volatile mode of operation is longer than the time that is sufficient to reset the RRAM cell to the RESET state using the same current while operating in the volatile mode of operation.

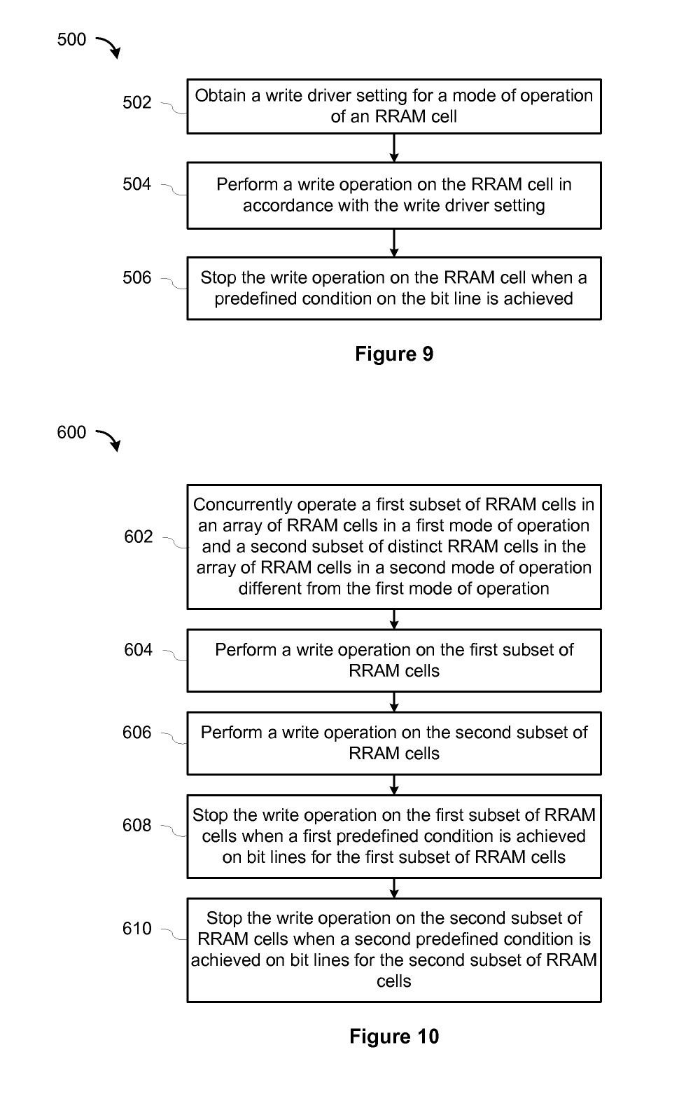

FIG. 10 is a flowchart showing an example of a method 600 for operating RRAM cells. In block 602, the RRAM device concurrently operates a first subset of the RRAM cells in an array of RRAM cells in a first mode of operation and a second subset of the RRAM cells, distinct from the first subset of the RRAM cells, in the array of RRAM cells, in a second mode of operation distinct from the first mode of operation. In one example, the first mode of operation is a volatile mode of operation and the second mode of operation is a non-volatile mode of operation.

In block 604, the RRAM device performs a write operation on the first subset of the RRAM cells. In block 606, the RRAM device additionally performs a write operation on the second subset of the RRAM cells. In block 608, respective disable circuits included in one or more respective first controlled write drivers 151 stop the first controlled write drivers from continuing to perform the write operation on the first subset of RRAM cells when a first predefined condition is achieved on bit lines for the first subset of the RRAM cells. The first predefined condition is based on the first mode of operation. In an example, in the first mode of operation, the RRAM cell has faster write performance and a shorter data retention time than the second mode of operation, and the first predefined condition depends on a resistance value of the RRAM cells (e.g., a higher resistance value). In block 610, respective disable circuits included in one or more respective second controlled write drivers 151 stop the second controlled write drivers from continuing to perform the write operation on the second subset of the RRAM cells when a second predefined condition is achieved on bit lines for the second subset of RRAM cells. The second predefined condition depends on the second mode of operation. In an example, the second mode of operation has slower write performance and a longer data retention time than the first mode of operation, and the second predefined condition depends the resistance value of the RRAM cells (e.g., a lower resistance value than in the first mode of operation).

In some embodiments, the mode of operation is set by mode selection logic. The mode selection logic is logic included in the RRAM device (e.g., in control logic 306 and/or in controlled write driver 151) that sets the mode of operation of RRAM cells. The mode selection logic may be controlled by commands issued by a host processor or memory controller. In some embodiments, after setting the mode of operation for a respective memory cell, the RRAM device rewrites the data stored in the respective RRAM cell based on the selected mode of operation. For example, if the data stored in the respective RRAM cell is stored in the non-volatile mode of operation (e.g., a mode having a longer data retention time and a slower write performance) and the RRAM device sets the mode of operation to a volatile mode of operation (e.g., a mode having a shorter data retention time and faster write performance), the RRAM device rewrites the data in the respective RRAM cell so that the data is stored in the volatile mode of operation. Accordingly, if the respective RRAM cell was in a SET state in which the resistance of the respective RRAM cell is relatively low, the RRAM device performs a reset operation controlled to increase the resistance of the respective RRAM cell until the resistance of the RRAM cell is within the range of resistances for the SET state that corresponds to the volatile mode of operation. Alternatively, the RRAM device performs a reset operation to place the RRAM cell into the RESET state and then performs a set operation controlled to place the resistance of the RRAM cell within the range of resistances for the SET state that corresponds to the volatile mode of operation. In some embodiments, analogous operations are performed for RRAM cells when switching from the volatile mode of operation to the non-volatile mode of operation and for RRAM cells in a RESET state.

In some embodiments, the RRAM device sets the mode of operation of the RRAM cell based on a system event. In an example, the RRAM device changes the mode of operation of the RRAM cell from the volatile mode of operation to the non-volatile mode of operation during a system shutdown operation. In another example, the RRAM device sets the mode of operation of the RRAM cell from the volatile mode of operation to the non-volatile mode of operation during a system hibernation operation. In another example, the RRAM device sets the mode of operation of the RRAM cell from the volatile mode of operation to the non-volatile mode of operation in response to a loss of power. In yet another example, the RRAM device sets the mode of operation of the RRAM cell from the non-volatile mode of operation to the volatile mode of operation when a system that includes the RRAM device is set to a high-performance mode.

In some embodiments, the mode of operation is user-programmable. In some embodiments, the mode of operation is not user-programmable.

In some embodiments, methods 500 and 600 are governed, at least in part, by instructions stored in a non-transitory computer readable storage medium and that are executed by one or more processors or state machines of an electronic device. In these embodiments, one or more of the operations shown in FIGS. 8 and 9 correspond to instructions stored in a non-transitory computer readable storage medium. Examples of a computer readable storage medium include a magnetic or optical disk storage device, solid state storage devices such as flash memory, or other non-volatile memory device or devices. The instructions stored on the computer readable storage medium are in source code, assembly language code, object code, or another instruction format that is interpreted and/or executable by one or more processors or state machines.

The foregoing description, for purpose of explanation, has been described with reference to specific embodiments. However, the illustrative descriptions above are not intended to be exhaustive or to limit the claims to the precise forms disclosed. Many modifications and variations are possible in view of the above teachings. The embodiments were chosen and described in order to best explain the principles of the invention and its practical applications, to thereby enable others to best utilize the invention and various embodiments with various modifications as are suited to the particular use contemplated.

What is claimed is:

1. A resistive RAM device, comprising:
a bit line;
a word line;
an RRAM cell coupled to the word line and the bit line;
a write driver coupled to the bit line; and
a disable circuit for stopping a write operation performed by the write driver on the RRAM cell when a predefined condition on the bit line is achieved, the predefined condition depending on a mode of operation of the RRAM cell.

2. The resistive RAM device of claim 1, wherein the predefined condition on the bit line corresponds to a predefined SET state condition of the RRAM cell.

3. The resistive RAM device of claim 2, wherein the predefined SET state condition depends on a resistance of the RRAM cell.

4. The resistive RAM device of claim 1, wherein the disable circuit comprises a circuit to detect when a voltage on the bit line is less than or equal to a reference voltage associated with the predefined condition.

5. The resistive RAM device of claim 1, wherein the disable circuit comprises a circuit to detect when the current on the bit line is greater than or equal to a reference current associated with the predefined condition.

6. The resistive RAM device of claim 1, wherein the disable circuit comprises a delay circuit to delay the stopping of the write operation on the RRAM cell based on a delay setting.

7. The resistive RAM device of claim 1, wherein:
the mode of operation of the RRAM cell is one of a plurality of modes of operation, and
each of the modes of operation corresponds to a distinct data retention time of the RRAM cell.

8. The resistive RAM device of claim 1, wherein:
the mode of operation of the RRAM cell is one of a volatile mode of operation and a non-volatile mode of operation, and
the RRAM cell has faster write performance and a shorter data retention time in the volatile mode of operation than in the non-volatile mode of operation.

9. The resistive RAM device of claim 8, wherein, when the RRAM cell is in a SET state, the RRAM cell has a higher resistance when operating in the volatile mode of operation than when operating in the non-volatile mode of operation.

10. The resistive RAM device of claim 8, wherein a current sufficient to reset the RRAM cell to a predefined RESET state in a defined time when operating in the non-volatile mode of operation is higher than the current sufficient to reset the RRAM cell to the predefined RESET state in the defined time when operating in the volatile mode of operation.

11. The resistive RAM device of claim 8, wherein a time sufficient to reset the RRAM cell to a predefined RESET state using a defined current when operating in the non-volatile mode of operation is longer than the time that is sufficient to reset the RRAM cell to the predefined RESET state when operating in the volatile mode of operation.

12. The resistive RAM device of claim 8, additionally comprising mode selection logic to set the mode of operation of the RRAM cell based on a system event.

13. The resistive RAM device of claim 8, additionally comprising mode selection logic to set the mode of operation of the RRAM cell to the non-volatile mode of operation during a system shutdown operation.

14. The resistive RAM device of claim 8, additionally comprising mode selection logic to set the mode of operation of the RRAM cell to the non-volatile mode of operation during a system hibernation operation.

15. The resistive RAM device of claim 8, additionally comprising mode selection logic to set the mode of operation of the RRAM cell to the non-volatile mode of operation in response to a loss of power.

16. The resistive RAM device of claim 8, additionally comprising mode selection logic to set the mode of operation of the RRAM cell to the volatile mode of operation in response to a system event that includes the resistive RAM device being set to a high-performance mode.

17. The resistive RAM device of claim 1, wherein:
the mode of operation is one of a plurality of modes of operation of the RRAM cell, the modes of operation comprising a volatile mode of operation and a non-volatile mode of operation, and
the resistive RRAM device additionally comprises control logic to rewrite data stored in the RRAM cell when the mode of operation of the RRAM cell is changed from the volatile mode of operation to the non-volatile mode of operation.

18. The resistive RAM device of claim 1, wherein
the mode of operation is one of a plurality of modes of operation of the RRAM cell, the modes of operation comprising a volatile mode of operation and a non-volatile mode of operation, and
the resistive RRAM device comprises control logic to rewrite data stored in the RRAM cell when the mode of operation of the RRAM cell is changed from the non-volatile mode of operation to the volatile mode of operation.

19. The resistive RAM device of claim 1, wherein:
the RRAM cell is included in an array of RRAM cells, the array comprising:
a set of bit lines that includes the bit line; and
a set of word lines that includes the word line;
each RRAM cell in the array of RRAM cells is coupled to a respective word line of the set of word lines and to a respective bit line of the set of bit lines;
the write driver is one of a set of write drivers, and each write driver in the set of write drivers is coupled to a respective bit line;
the disable circuit is one of a set of disable circuits, each disable circuit for stopping a write operation performed by the respective write driver on a respective RRAM cell when a predefined condition on the respective bit line is achieved, the predefined condition depending on a mode of operation of the respective RRAM cell; and
the resistive RAM device additionally comprises a configuration storage device configured to store settings for controlling operation of the set of disable circuits in corresponding modes of operation of the RRAM cells.

20. The resistive RAM device of claim 19, wherein:
a first subset of the RRAM cells in the array of RRAM cells is configured to operate in a first mode of operation,
a second subset of the RRAM cells in the array of RRAM cells is configured to operate in a second mode of operation different from the first mode of operation, and
the RRAM cells in the first subset of the RRAM cells and in the second subset of the RRAM cells are different.

21. The resistive RAM device of claim 1, wherein the mode of operation is user-programmable.

22. A method of operating a resistive RAM device, the RRAM device comprising a controlled write driver coupled to an RRAM cell via a bit line, the method comprising:
performing a write operation on the RRAM cell in accordance with a write driver setting for a mode of operation of the RRAM cell, wherein the write driver setting is one of a plurality of distinct write driver settings for controlling operation of the controlled write driver in a corresponding plurality of modes of operation of the RRAM cell; and
stopping the write operation on the RRAM cell when a predefined condition on the bit line is achieved, the predefined condition depending on the mode of operation of the RRAM cell.
